(19) United States
(12) Patent Application Publication
(10) Pub. No.: US 2026/0223342 A1
(43) Pub. Date: Jul. 30, 2026

(54) SHROUD ASSEMBLIES FOR PRINTED CIRCUIT BOARDS

(71) Applicant: ARRIS Enterprises LLC, Horsham, PA (US)

(72) Inventors: David Richard WILLIAMS, Mount Laurel, NJ (US); Pedro C. RAMIREZ MENESES, North Wales, PA (US); Jinwoo LEE, Souderton, PA (US)

(73) Assignee: ARRIS Enterprises LLC, Horsham, PA (US)

(21) Appl. No.: 19/141,850

(22) PCT Filed: Dec. 20, 2023
(86) PCT No.: PCT/US23/85224

§ 371 Date: Jun. 20, 2025

Related U.S. Application Data
(60) Provisional application No. 63/433,930, filed on Dec. 20, 2022.

(51) Int. Cl. H05K 9/00

(52) U.S. Cl. CPC H05K 9/0024

(57) ABSTRACT

Shroud assemblies are shown and disclosed. In one embodiment, the shroud assembly includes a housing having a plurality of walls collectively defining a cavity sized to receive a printed circuit board (PCB) having a plurality of pins. The housing includes one or more retainers that secure the PCB to one or more walls of the plurality of walls. The shroud assembly additionally includes a handle attached to the housing. In other embodiments, the housing includes a first keying structure that corresponds to a second keying structure of at least one wall that at least partially defines an opening of an assembly distinct and separate from the shroud assembly. The opening sized to receive the housing of the shroud assembly. The first and second keying structures positioned to allow the opening to receive the housing in only a predetermined orientation. In other embodiments, the assembly includes an electromagnetic interference (EMI) shield.

### CROSS REFERENCE TO RELATED APPLICATIONS

The present application claims the benefit of U.S. Provisional Patent Application No. 63/433,930 filed Dec. 20, 2022, the contents of which are each incorporated herein by reference in their entirety.

### BACKGROUND

The subject matter of this application relates to shroud assemblies for printed circuit boards (PCBs) and other electronic components. PCBs and other electronic components have pins that are received in sockets of electronic devices that are distinct and separate. There are times when the PCBs must be separated from the electronic devices so the pins of the PCBs must be separated from the sockets of the electronic devices and then reinstalled in the future. During removal and installation, the user must be careful to not damage the various components attached to the PCB. Additionally, when the pins of the PCB are received in the sockets, operation of the PCB may emit radiofrequency (RF) signals that may interfere with one or more other components of the electronic device.

What is desired, therefore, are shroud assemblies that receive a PCB and protect the PCB components, that allow easy installation and removal of the PCB, and/or that shield any RF signals from escaping the immediate area of the PCB.

### BRIEF DESCRIPTION OF THE DRAWINGS

For a better understanding of the invention, and to show how the same may be carried into effect, reference will now be made, by way of example, to the accompanying drawings, in which:

FIG. 1 is an isometric view of an example of a shroud assembly.

FIG. 2 is another isometric view of the shroud assembly of FIG. 1.

FIG. 3 is a front view of the shroud assembly of FIG. 1.

FIG. 4 is a bottom view of the shroud assembly of FIG. 1.

FIG. 5 is an exploded view of the shroud assembly of FIG. 1.

FIG. 6 is an isometric view of the shroud assembly of FIG. 1 with a PCB attached.

FIG. 7 is a front view of the shroud assembly of FIG. 6.

FIG. 8 is a bottom view of the shroud assembly of FIG. 6.

FIG. 9 is a partial view of an example of an electronic device having an opening that receives the shroud assembly of FIG. 6.

### DETAILED DESCRIPTION

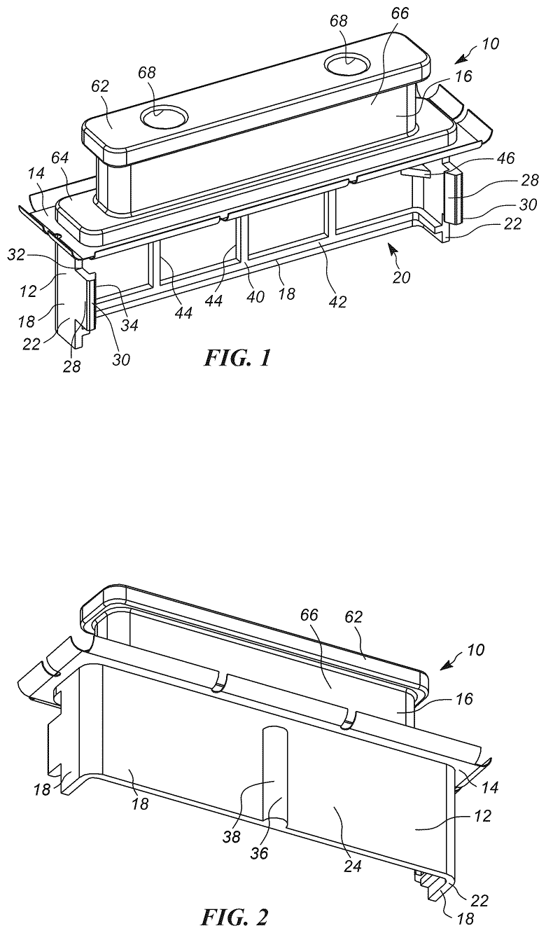

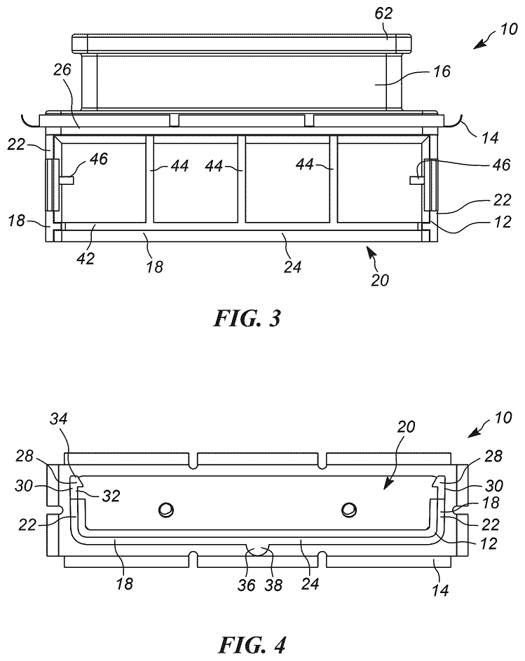

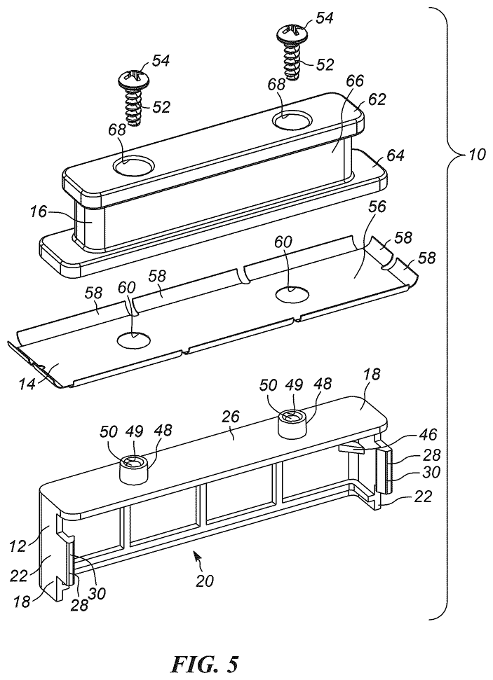

Referring to FIGS. 1-5, an example of a shroud assembly 10 is shown. The shroud assembly includes a housing 12, an electromagnetic interference (EMI) shield 14, and a handle 16. In the example shown in FIGS. 1-5, the EMI shield is disposed between the housing and the handle.

Housing 12 includes a plurality of walls 18 that define a cavity 20 sized to receive at least one printed circuit board (PCB) and/or other electronic component(s). In the example shown in FIGS. 1-5, walls 18 include opposed side walls 22, a back wall 24 connecting and/or spanning the side walls, and a top wall 26 connecting and/or spanning the back wall and the side walls. Side walls 22, back wall 24, and top wall 26 collectively define cavity 20. However, other examples of housing 12 may define cavity 20 with less than all walls 18. In the example shown in FIGS. 1-5, walls 18 are formed together. However, other examples of housing 12 may include one or more walls 18 that are attached together.

Housing 12 additionally includes one or more retainers 28 that secure a PCB in cavity 20 and/or to one or more of walls 18. The retainers may be attached to, or formed with, one or more of walls 18. Retainers 28 may include any suitable structures. In the example shown in FIGS. 1-5, retainers 28 are in the form of cantilever snaps 30 each having a beam or planar portion 32 and a catch or receiving portion 34. Other examples of retainers 28 may include mounting bosses, mounting standoffs, and mounting rails (and their associated fasteners, if applicable). Retainers 28 may be attached to, or formed with, one or more walls 18 of housing 12. In the example shown in FIGS. 1-5, retainers 28 are formed with side walls 22. However, other examples of housing 12 may include retainers 28 attached to, or formed with, top wall 26 and/or back wall 24 instead of, or in addition to, side walls 22.

Housing 12 further includes one or more keying structures 36 that correspond to keying structures of an assembly or device that is distinct and separate from shroud assembly 10. The keying structures 36 of housing 12 require the user to attach the housing 12 and/or the PCB received in cavity 20 only in a predetermined orientation and/or position. In the example shown in FIGS. 1-5, keying structure 36 includes at least one tab or protrusion 38 that corresponds to at least one groove or channel of the separate assembly or device. Other examples of keying structure 36 include projecting structures, holes, threads, etc.

Housing 12 additionally includes one or more ribs or reinforcing structures 40 that are attached to, or formed with, one or more walls 18. In the example shown in FIGS. 1-5, ribs 40 includes a U-shaped horizontal rib 42 and three spaced vertical ribs 44 attached to, or formed with, the horizontal rib. The U-shaped horizontal rib is formed with side walls 22 and back wall 24 and vertical ribs 44 are formed with the back wall. Ribs 40 also includes ramps 46 formed with side walls 22 and back wall 24. However, other examples of housing 12 may include ribs or reinforcing structures having different shapes and/or sizes.

In the example shown in FIGS. 1-5, housing 12 further includes one or more bosses or projecting structures 48 attached to, or formed with, top wall 26. Bosses 48 each includes apertures 49 having threads 50 that correspond to threads 52 of fasteners 54. In the example shown in FIGS. 1-5, fasteners 54 are screws but other examples of fasteners 54 include bolts and other suitable fasteners. Additionally, other examples of housing 12 may exclude or omit threads 50 (such as when fasteners do not include corresponding threads) or exclude or omit bosses 48 (such as when top wall 26 includes apertures 49 without bosses 48). In other examples, housing 12, EMI shield 14, and/or handle 16 may be attached together without fasteners 54, such as via ultrasonic welding.

EMI shield 14 includes a base portion 56 and extending portions 58. In the example shown in FIGS. 1-5, base portion 56 is planar and extending portions are flared. Base portion 56 is a substantial portion of EMI shield 14 and is attached to top wall 26 of housing 12. The base portion includes one or more holes 60 that receive bosses 48 of top wall 26 and/or fasteners 54. However, the EMI shield may alternatively, or additionally, be attached to one or more other walls of plurality of walls 18.

Extending portions 58 are attached to, or formed with, base portion 56. The extending portions are spaced from each other. Although two spaced extending portions 58 are shown attached to, or formed with, each end of base portion 56 and three spaced extending portions 58 are shown attached to, or formed with, each side of base portion 56, other examples of EMI shield 14 may include less or more extending portions. For example, a single extending portion 58 may be attached to, or formed with, each end of base portion 56, and/or a single or two spaced extending portion(s) 58 may be attached to, or formed with, each side of base portion 56.

The EMI shield is disposed between the handle and the housing. In other words, the EMI shield is “sandwiched” between the handle and the housing (e.g., “sandwiched” between two halves when the handle and housing have the same approximate dimensions). EMI shield 14 is sized to fully or at least substantially cover or span an opening that the housing is received in to block any potential RF leak from the PCB received in cavity 20 of housing 12, as further discussed below.

Handle 16 is attached to EMI shield 14 and/or housing 12, such as to top wall 26 of housing 12. The handle may, however, be alternatively, or additionally be attached to one or more other walls 18 of housing 12. Handle 16 may be any suitable shape(s) and/or size(s). In the example shown in FIGS. 1-5, handle 16 includes two planar or flat portions 62, 64 and a cuboid portion 66 disposed between the planar portions. Planar portions 62, 64 and cuboid portions 66 each includes one or more openings 68 that corresponds with aperture(s) 49 of housing 12 and/or holes 60 of EMI shield 14, which receives fasteners 54 to attach, secure, or fasten handle 16 to EMI shield 14 and/or housing 12. Although handle 16 is shown to be attached to housing 12, the handle may in some embodiments be formed with housing 12. In those embodiments, the housing and/or handle may include a slot or opening that receives EMI shield 14.

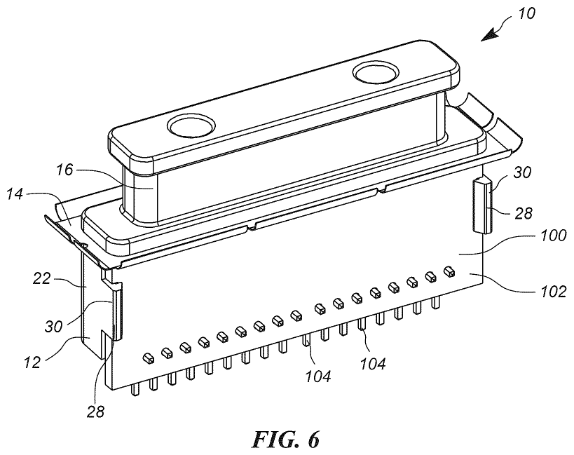

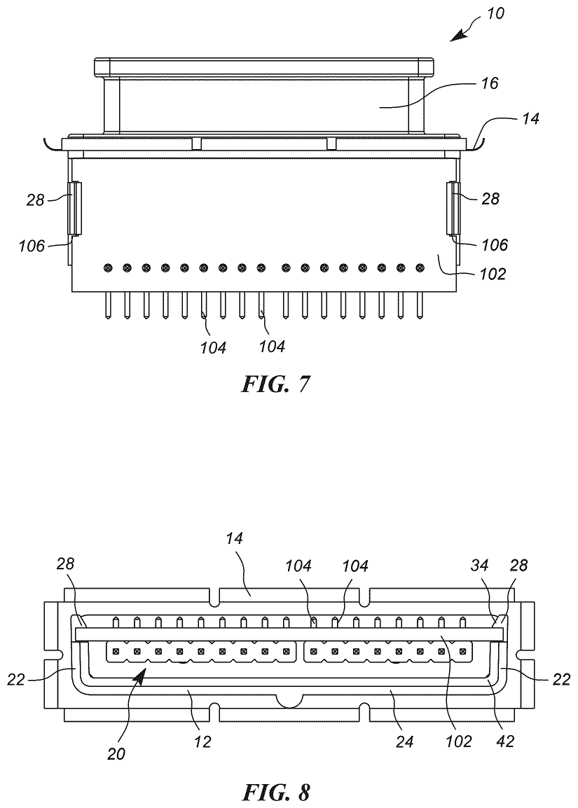

Referring to FIGS. 6-8, shroud assembly 10 is shown with a PCB 100 received in cavity 20. PCB 100 includes a board 102 and a plurality of pins 104. In the example shown in FIGS. 6-8, PCB 100 additionally includes opposed cutouts or openings 106 that each receive a portion of a retainer 28. When retainers 28 are in the form of cantilever snaps 30, PCB 100 rests or is supported between catch portion 34 and side walls 22 (and/or U-shaped horizontal rib 42). When PCB 100 is secured to housing 12 as shown in FIGS. 6-8, a substantial portion of the volume of cavity 20 is available to accommodate or receive electronic components (not shown) attached to board 102. In other words, side walls 22 have a height such that board 102 is secured at a position spaced from back wall 24 to provide clearance between board 102 and back wall 24 for the electronic components attached to that board, as best shown in FIG. 8.

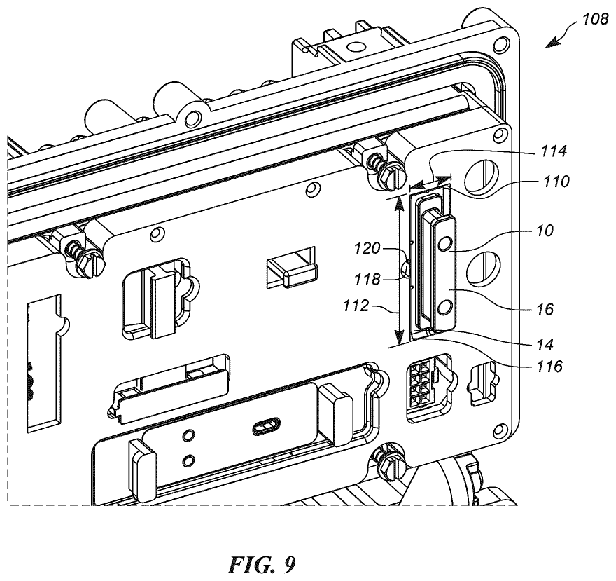

Referring to FIG. 9, an example of an electronic device 108 that receives shroud assembly 10 and PCB 100 is shown. Electronic device 108 includes one or more slots, cavities, or openings 110 that receive shroud assembly 10 with PCB attached to that assembly. Opening 110 includes a length 112 and a width 114. As shown in FIG. 9, EMI shield 14 of shroud assembly 10 has a length and width that is substantially the same as length 112 and width 114 to substantially cover opening 110 to block any potential RF leak from PCB 100. Housing 12 of shroud assembly 10 is sized such that, when shroud assembly and PCB 100 is inserted into opening 110, at least the housing and EMI shield 14 are received in the opening with all or most of handle 16 extending outside of opening 110 to facilitate insertion and removal of shroud assembly 10.

Slot 110 is defined by a plurality of walls 116 with one or more of those walls having at least one keying structure 118 that corresponds to at least one keying structure 36 of housing 12 to ensure insertion of shroud assembly in a predetermined orientation. In the example shown in FIG. 9, keying structure 118 is in the form of a groove or channel 120. Other examples of keying structure 118 include tabs, protrusions, projecting structures, holes, threads, etc. The bottom surface or wall (not shown) of slot 110 includes sockets and/or other structures that receive pins 104 of PCB 100.

The shroud assemblies of the present disclosure protect PCB components and allows for easy installation and extraction of the PCB. Other advantages of the present disclosure include the shielding of RF signals to prevent those signals from escaping the cavity that the PCB is installed. Additionally, having the EMI shield as part of the shroud assembly allows for easier and quicker installation without the need for a separate and/or loose shield that could otherwise become lost or damaged. Moreover, the keying feature(s) or keying structure(s) of the shroud assembly acts as an orientation key and a guide for easier installation of the shroud assembly.

It will be appreciated that the invention is not restricted to the particular embodiment that has been described, and that variations may be made therein without departing from the scope of the invention as defined in the appended claims, as interpreted in accordance with principles of prevailing law, including the doctrine of equivalents or any other principle that enlarges the enforceable scope of a claim beyond its literal scope. Unless the context indicates otherwise, a reference in a claim to the number of instances of an element, be it a reference to one instance or more than one instance, requires at least the stated number of instances of the element but is not intended to exclude from the scope of the claim a structure or method having more instances of that element than stated. The word “comprise” or a derivative thereof, when used in a claim, is used in a nonexclusive sense that is not intended to exclude the presence of other elements or steps in a claimed structure or method.

1. A shroud assembly, comprising:
a housing having a plurality of walls collectively defining a cavity sized to receive a printed circuit board (PCB) having a plurality of pins, wherein the housing includes one or more retainers that secure the PCB to one or more walls of the plurality of walls; and
a handle attached to the housing.

2. The assembly of claim 1, wherein the plurality of walls includes opposed side walls, a back wall connecting the side walls, and a top wall connecting the back wall and the side walls, wherein the side walls, back wall, and top wall collectively define the cavity.

3. The assembly of claim 2, wherein the handle is attached to the top wall.

4. The assembly of claim 2, wherein the one or more retainers are attached to, or formed with, at least one side wall of the opposed side walls.

5. The assembly of claim 4, wherein the one or more retainers each includes a cantilever snap.

6. The assembly of claim 2, wherein one or more walls of the plurality of walls include a first keying structure that corresponds to a second keying structure of at least one wall that at least partially defines an opening of an electronic assembly distinct and separate from the shroud assembly, the opening sized to receive at least the housing of the shroud assembly, the first and second keying structures positioned to allow the opening to receive at least the housing of the shroud assembly in only a predetermined orientation.

7. The assembly of claim 6, wherein the back wall includes the first keying structure.

8. The assembly of claim 1, wherein the plurality of walls is formed together.

9. The assembly of claim 1, wherein the handle includes at least one opening and the housing includes at least one aperture that corresponds to the at least one opening, further comprising a fastener received in the at least one opening of the handle and the at least one aperture of the housing to secure the handle to the housing.

10. The assembly of claim 1, further comprising an electromagnetic interference (EMI) shield disposed between the handle and the housing.

11. The assembly of claim 10, wherein the handle includes at least one opening, the EMI shield includes at least one hole that corresponds to the at least one opening, and the housing includes at least one aperture that corresponds to the at least one opening and the at least one hole, further comprising a fastener received in the at least one opening of the handle, the at least one hole of the EMI shield, and the at least one aperture of the housing to secure the handle and the EMI shield to the housing.

12. A shroud assembly, comprising:
a housing having a plurality of walls collectively defining a cavity sized to receive a printed circuit board (PCB) having a plurality of pins, wherein the housing includes a first keying structure that corresponds to a second keying structure of at least one wall that at least partially defines an opening of an electronic assembly distinct and separate from the shroud assembly, the opening sized to receive at least the housing of the shroud assembly, the first and second keying structures positioned to allow the opening to receive the housing of the shroud assembly in only a predetermined orientation.

13. The assembly of claim 12, wherein the first keying structure is at least one tab or protrusion formed with at least one wall of the plurality of walls, and the second keying structure is at least one groove or channel formed with the at least one wall that at least partially defines the opening of the electronic assembly.

14. The assembly of claim 12, further comprising an electromagnetic interference (EMI) shield attached to at least one wall of the plurality of walls.

15. A shroud assembly, comprising:
a housing having a plurality of walls collectively defining a cavity sized to receive a printed circuit board (PCB) having a plurality of pins; and
an electromagnetic interference (EMI) shield attached to at least one wall of the plurality of walls.

16. The assembly of claim 15, wherein the housing is sized be received in of an opening of an electronic assembly distinct and separate from the shroud assembly, and wherein the EMI shield at least substantially covers the opening when the housing is received in the opening.

17. The assembly of claim 15, wherein a substantial portion of the EMI shield is planar.

18. The assembly of claim 15, wherein the EMI shield includes one or more peripheral portions that curve away from the housing.
